(19) United States
(12) Patent Application Publication
(10) Pub. No.: US 2026/0291366 A1
(43) Pub. Date: Sep. 24, 2026

(54) SINGLE-ENDED DC-TO-DC CONVERTER

(71) Applicant: Vladimir Anatolyevich POLIKARPOV, Moscow (RU)

(72) Inventors: Vladimir Anatolyevich POLIKARPOV, Moscow (RU); Anatoliy Grigoryevich POLIKARPOV, Moscow (RU)

(21) Appl. No.: 19/153,537

(22) PCT Filed: Feb. 2, 2024
(86) PCT No.: PCT/RU2024/000027

§ 371 Date: Jun. 12, 2026

(30) Foreign Application Priority Data
Feb. 2, 2023 (RU) 2023102270

(51) Int. Cl. H02M 1/00; H02M 1/08; H02M 3/335; H03K 17/284

(52) U.S. Cl. CPC H02M 1/0054; H02M 1/08; H02M 3/33507; H03K 17/284; H03K 2217/0036

(57) ABSTRACT

The invention relates to electrical engineering, in particular to single-ended DC voltage converters, and can be used in secondary power supply systems to convert, regulate and stabilize the DC output voltage.

The purpose of the invention is to generate a constant output voltage from a constant input voltage and reduce dynamic losses.

The device contains a control switch 3, implemented in the form of a field-effect transistor (MOSFET), the control electrode of which is connected to a pulse width controller 10. A power transformer 2, the primary winding 1 of which is connected via a control switch 3 to a constant input voltage source, and the secondary winding 4 is connected via rectifier diodes 5,8 to series-connected filter capacitors 6,7, in parallel to which the load 9 is connected.

In the proposed single-ended DC converter, the beginning of the primary winding 1 of transformer 2 is connected to the positive pole of the input DC voltage source, and the end of the primary winding 1 is connected to its negative pole via a switch 3 controlled by a pulse width controller 10. The anode of the rectifier diode 5 is connected to the beginning of the secondary winding 4 of transformer 2, the cathode of which is connected to one of the terminals of capacitor 6. The second terminal of capacitor 6 is connected to the end of winding 4. The end of the winding 4 is connected to one of the terminals of the capacitor 7, the second terminal of which is connected to the anode of the rectifier diode 8, the cathode of which is connected to the beginning of the winding 4. The load 9 is connected in parallel with series-connected filter capacitors 6 and 7.

The invention pertains to the field of electrical engineering, specifically to single-ended DC voltage converters, and can be used in secondary power supply systems to convert, stabilize, and regulate the constant output voltage, which is electrically isolated from the input DC voltage.

There are known DC voltage converters with galvanic separation of the output DC voltage from the DC input voltage [1].

The disadvantage of known DC input voltage converters to constant output voltage is a limited range of output voltage regulation, increased requirements for gaps in the transformer magnetic core, trapezoidal current shape through the control switch, large dynamic losses in the control switch when it is turned on and off.

The closest technical solution to the proposed device is a DC-to-DC converter with energy transfer to the reverse output circuit (Flyback converter), which consists of a primary transformer winding connected to the input DC voltage source through a controlled switch, a secondary transformer winding connected to a rectifier diode and a capacitive filter, with the load connected in parallel to the filter.

The disadvantages of this converter are that it only transfers energy to the load during the time when the control switch is off, which limits the converter's voltage regulation capabilities. Additionally, it requires a significant gap in the magnetic circuit, resulting in associated losses in the transformer. Furthermore, there are significant dynamic power losses in the control switch during the on and off intervals, due to the trapezoidal shape of the current flowing through the control switch.

The object of the invention is to overcome these disadvantages.

This objective is accomplished by the fact that in a single-ended DC voltage converter, the primary winding of the transformer is connected through a control switch to the terminals of the input DC voltage source, the secondary winding of the transformer is connected through a rectifier diode to the first filter capacitor, and through another rectifier diode to the second filter capacitor connected in series with the first filter capacitor, in parallel with which the load is connected.

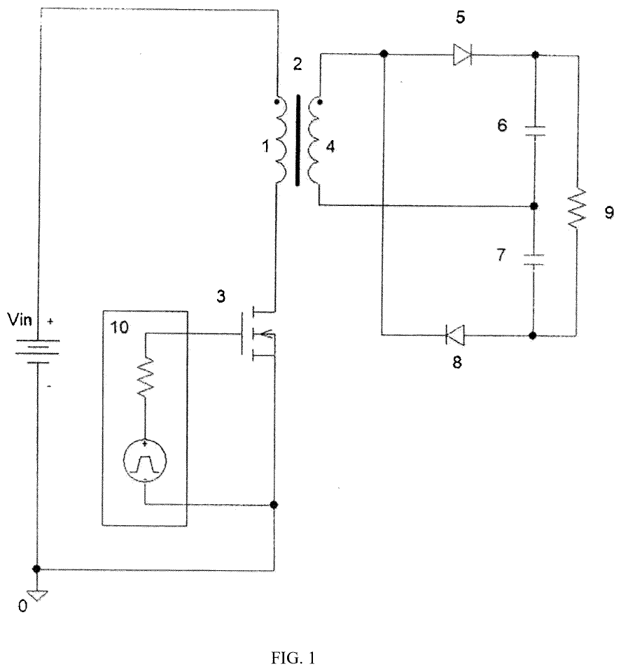

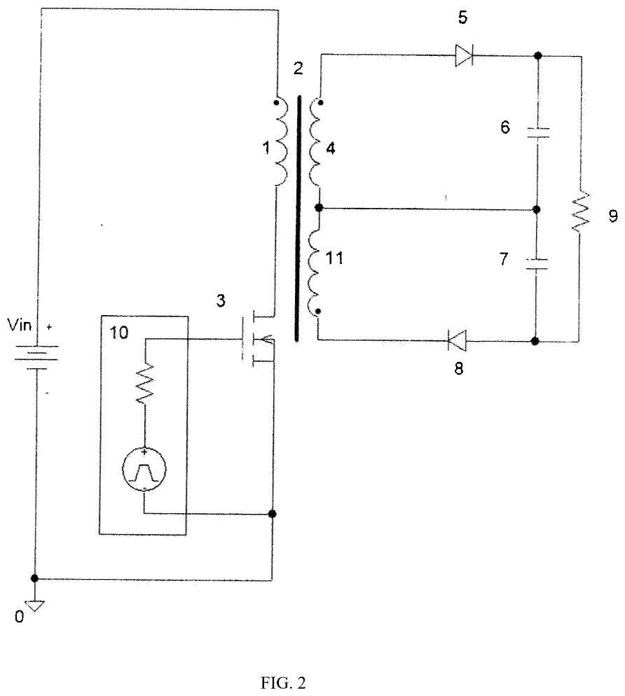

FIGS. 1 and 2 illustrate the schematic diagrams of the proposed single-ended DC voltage converter. FIG. 1 depicts a schematic diagram of a single-ended DC voltage converter; FIG. 2 depicts a schematic diagram of a single-ended DC voltage converter with an additional winding.

In FIG. 1, the beginning of the primary winding 1 of the transformer 2 is connected to the positive pole of the input DC voltage source, and the end of the primary winding 1 is connected to the negative pole of the input DC voltage source through the pulse-width controller 10 controlled by the pulse-width controller 10. With the beginning of the secondary winding 4 of the transformer 2, the anode of the rectifier diode 5 is connected, the cathode of which is connected to one of the terminals of the capacitor 6. The second terminal of the capacitor 6 is connected to the end of the winding 4. The end of the winding 4 is connected to one of the terminals of the capacitor 7, the second terminal of which is connected to the anode of the rectifier diode 8, the cathode of which is connected to the beginning of the winding 4. The load 9 is connected in parallel to the capacitors 6 and 7 connected in series.

In FIG. 2, the end of the additionally introduced winding 1 of the transformer 2 is connected to one of the terminals of the capacitor 7, the second terminal of which is connected to the anode of the rectifier diode 8, the cathode of which is connected to the beginning of the winding 11.

The operation of the proposed single-ended DC voltage converter is based on the preposition of the ideality of switch elements, the steady-state mode of operation and the continuity of the change in the magnetic flux in the core of the transformer 2.

In this case, at the stage of the closed state DT of the switch 3 made on the field-effect transistor (MOSFET), the energy is transferred to the load through the forward-biased rectifier diode 5 and the winding 4. In this case, due to the balance of charges at time intervals DT and (1−D)T of the capacitor 6, current IL/D flows through the rectifier diode 5, where IL is the load current, and the voltage on the capacitor 7 is determined by the expression nVIN where n is the ratio of the turns of the winding 4 to the winding 1.

After switching off the switch 3 in the time interval (1−D)T, the voltage across the windings of the transformer 2 changes the sign. As a consequence, the rectifier diode 5 is closed and the diode 8 opens and the stored energy in the transformer 2 in the time interval DT, the on-state of the switch 3, is discharged into to the capacitor 7 through the rectifier diode 8 and the secondary winding 4 of the transformer 2. In this case, due to the balance of the charges of the capacitor 7, current IL/(1−D) flows through the rectifier diode 8, and the voltage on the capacitor 7 is determined by the expression nVIND/(1−D). The output voltage at the load the nVIN/(1−D) is determined by the sum of voltages on the capacitors 6 and 7, which are connected in series.

When energy is transferred to the output circuit in the time interval DT, the on-state of the switch 3, two processes take place: one of which is associated with one-time magnetization of the transformer 2 through the primary winding 1 from the input voltage source VIN and the secondary winding 4 from the voltage nVIN on the capacitor 6. As a result of these magnetizations, the currents are proportionally increased. In the secondary winding 4, the rise of this current leads to a decrease in current through the rectifier diode 5 being in the conducting state in this time interval. The linear reduction of the current through the rectifier diode 5 transformed into the primary winding 1 and compensates for the linear rise of the current through the primary winding 1, which leads to the rectangular form of the current through the control switch 3.

The second process is related to the moment of switching on the control switch 3. When the control switch 3 is turned on, the voltages on the transformer windings are reversed, leading to switching off the rectifier diode 8 and turning on the rectifier diode 5. However, the switching of the rectifier diode 5 occurs with a time delay with respect to the moment of switching on the control switch 3. This delay is due to the end time of voltage change on the windings of the transformer 2 and the positive potential at the cathode of the rectifier diode 5 equal to nVIN.

The time delay in transferring energy to the output circuit when the control switch 3 is turned on causes the current and voltage edges on the control switch 3 to be separated, reducing dynamic losses when the switch is turned on. As noted above, the current through the control switch 3 is of rectangular form, which reduces losses on the control switch 3 when it is turned off, since the switch is turned off for less current.

As can be seen from the operating principle of this single-ended DC voltage converter, the magnetization and demagnetization of the transformer 2 follows the output winding 4 of the transformer 2. In order to optimize the transformer 2 and reduce the gap therein, it is possible to magnetize and demagnetize it from different windings by introducing an additional winding 11, as shown in the drawing of FIG. 2

Consequently, the proposed single-ended DC voltage converter, in contrast to the existing device, enables the transfer of energy to the load throughout the entire operational period T of the converter, enhancing its control and power capabilities. Due to the specifics of energy transfer to the output circuit in the form of a voltage pulse and a current pulse enables to form a time delay in energy transfer to the output circuit when the control switch 3 is turned on. And thus, it allows to separate the current rise and the voltage drop through the control switch, which significantly reduces the power loss on the switch when it is turned on, and the rectangular form of the current flowing through the switch 3 reduces losses on it when it is turned off.
1. [Polikarpov A.G., Sergienko E.F. Single-ended power converters in the power supply devices of electronic equipment, “Radio and communication”, 1989, p.47 FIG. 2.1].

### FORMULA OF THE INVENTION

1. A single-ended DC voltage converter comprising a transformer having a primary winding connected via a controlled switch to input terminals of a DC voltage source, a secondary winding connected via rectifier diodes to output terminals of the filter capacitors, characterized in that in order to generate a constant output voltage from the constant input voltage and reduce dynamic power losses, the secondary winding of the transformer is connected through a series-connected diode to the terminals of the first capacitor, and through the second series-connected diode, which outputs the reactive energy of the transformer, is connected to the terminals of the second capacitor, connected in series with the first, parallel to which the load is connected.
2. The single-ended DC voltage converter according to claim 1, characterized in that the optimization of the transformer is achieved by connecting to an additionally introduced secondary winding of the transformer of the diode performing the derivation of the reactive energy of the transformer.

1. A single-ended DC voltage converter comprising a transformer having a primary winding connected via a controlled switch to input terminals of a DC voltage source, a secondary winding connected via rectifier diodes to output terminals of the filter capacitors, characterized in that in order to generate a constant output voltage from the constant input voltage and reduce dynamic power losses, the secondary winding of the transformer is connected through a series-connected diode to the terminals of the first capacitor, and through the second series-connected diode, which outputs the reactive energy of the transformer, is connected to the terminals of the second capacitor, connected in series with the first, parallel to which the load is connected.

2. The single-ended DC voltage converter according to claim 1, characterized in that the optimization of the transformer is achieved by connecting to an additionally introduced secondary winding of the transformer of the diode performing the derivation of the reactive energy of the transformer.
